(19) United States
(12) Patent Application Publication
(10) Pub. No.: US 2006/0196410 A1
(43) Pub. Date: Sep. 7, 2006

(54) Whisker-grown body and electrochemical capacitor using the same

(75) Inventors: Yoshiko Hishitani, Kawasaki-shi (JP); Makoto Uchiyama, Miura-shi (JP); Hidetoshi Nojiri, Yokohama-shi (JP)

Correspondence Address: FOLEY AND LARDNER LLP;SUITE 500, 3000 K STREET NW, WASHINGTON, DC, 20007, US

(73) Assignee: NISSAN MOTOR CO., LTD.

(21) Appl. No.: 11/354,242

(22) Filed: Feb. 15, 2006

(30) Foreign Application Priority Data
Feb. 16, 2005 (JP) 2005-038994
Dec. 8, 2005 (JP) 2005-354446
Jan. 18, 2006 (JP) 2006-010068

(51) Int. Cl. C30B 9/00; C30B 11/00; C30B 17/00; C30B 21/02; C30B 28/06

(52) U.S. Cl. 117/75

(57) ABSTRACT

A whisker-grown body of the present invention includes a raw material substrate made of manganese-containing metal and/or ceramics, and a whisker containing 50% by mass or more of manganese dioxide and formed on a surface of the raw material substrate. The whisker-grown body has a high surface ratio to unit volume and improves electrode efficiency when used as an electrode of an electrochemical capacitor.

### BACKGROUND OF THE INVENTION

1. Field of the Invention

The present invention relates to a whisker-grown body which includes a raw material substrate and manganese dioxide-based whiskers grown on the substrate and is preferably used as an electrode material or the like using conductivity of the whiskers. The present invention also relates to a manufacturing method of the whisker-grown body, as well as an electrochemical capacitor using the whisker-grown body.

2. Description of the Related Art

Electrochemical capacitors (electric double layer capacitors) are those which use an electric accumulation effect caused by electric double layers formed between an interface of two different substances, or by electrochemical absorption of ions or the like or oxidation reduction reaction of metal or the like which occurs on an electrode's surface. As to an electrode material used for such capacitors, porous conductive ceramics, obtained by sintering a gel made by a sol-gel process, has been suggested (see Japanese Patent Laid-Open Publication No. 2002-299164).

There is also a suggested capacitor electrode which is obtained as follows: surfaces of particles of carbon impalpable powder such as acetylene black are coated with a uniform thin-layer of metal oxide, metal nitride, or metal carbide. Thereafter, the carbon impalpable powder is mixed with carbon powder or the like and is applied onto a metal collector (see Japanese Patent Laid-Open Publication No. 2004-103669).

### SUMMARY OF THE INVENTION

The electrode material disclosed in Japanese Patent Laid-Open Publication No. 2002-299164 has characteristics of nano-order pores and wide surface area. However, since conductive ceramics has a very fine mesh structure, the electrode has high internal resistance, causing poor responsiveness.

As for the electrode material disclosed in Japanese Patent Laid-Open Publication No. 2004-103669, although it has a wide surface area, since carbon powder or the like has to be mixed as a separate step, effectiveness of the entire electrode is reduced, and a collector needs to be prepared separately.

The present invention has been accomplished to resolve the above problems found in the conventional electrode materials for electrochemical capacitors. An objective of the present invention is to provide a whisker-grown body which has a high surface ratio to unit volume and improves electrode efficiency when used as an electrode of a capacitor, a manufacturing method of the whisker-grown body, and an electrochemical capacitor using the whisker-grown body.

The first aspect of the present invention provides a whisker-grown body comprising: a raw material substrate made of manganese-containing metal and/or ceramics; and a whisker containing 50% by mass or more of manganese dioxide and formed on a surface of the raw material substrate.

The second aspect of the present invention provides a whisker-grown body comprising: a raw material substrate having a manganese-containing layer which is made of a manganese-containing metal and/or ceramics and is formed on a surface thereof; and a whisker containing 50% by mass or more of manganese dioxide and formed on a surface of the manganese-containing layer.

The third aspect of the present invention provides an electrochemical capacitor comprising: an electrode comprising: a raw material substrate made of manganese-containing metal and/or ceramics; and a whisker containing 50% by mass or more of manganese dioxide and formed on a surface of the raw material substrate.

The fourth aspect of the present invention provides An electrochemical capacitor comprising: an electrode comprising: a raw material substrate having a manganese-containing layer which is made of a manganese-containing metal and/or ceramics and is formed on a surface thereof; and a whisker containing 50% by mass or more of manganese dioxide and formed on a surface of the manganese-containing layer.

The fifth aspect of the present invention provides a manufacturing method of a whisker-grown body comprising: providing a raw material substrate made of manganese-containing metal or/and ceramics or a raw material substrate having a manganese-containing layer made of manganese-containing metal or/and ceramics; forming a whisker on a surface of the raw material substrate by a first heating treatment in an inert gas atmosphere containing oxygen, the whisker being made of a manganese-containing oxide; and performing a second heating treatment on the whisker in an oxidizing atmosphere.

### BRIEF DESCRIPTION OF THE DRAWINGS

The invention will now be described with reference to the accompanying drawings wherein;

FIG. 1 is a cross-sectional view schematically showing an embodiment of a whisker-grown body according to the present invention;

FIG. 2 is an enlarged view schematically showing whiskers according to the present invention;

FIG. 3 is a cross-sectional view schematically showing another embodiment of a whisker-grown body according to the present invention;

FIG. 4 is a cross-sectional view schematically showing an electrochemical capacitor using the whisker-grown body according to the present invention;

FIG. 5 is an electron microscopic picture of whiskers of a whisker-grown body obtained in Example 1;

FIG. 6 is a graph showing a relation between resistivity of whiskers obtained in a first step and oxidation time;

FIG. 7 is a chart showing a result of analysis of whisker's ingredients by EDX before oxidation in a second step;

FIG. 8 is a chart showing a result of analysis of whisker's ingredients by EDX after oxidation in the second step;

FIG. 9 is a chart showing a result of analysis of whiskers by O-K Edge ELNES after oxidation in the second step;

FIG. 10 is an electron microscopic picture of whiskers of a whisker-grown body obtained in Example 2;

FIG. 11 is an electron microscopic picture of whiskers of a whisker-grown body obtained in Example 3;

FIG. 12 is a graph showing measurement results of cyclic voltammetry for electrochemical capacitors using the whisker-grown bodies obtained in Examples 1 and 2 and Comparative Example; and

FIG. 13 is a graph showing cycle characteristics of electrochemical capacitors using the whisker-grown bodies obtained in Examples 1 and 2 and Comparative Example.

### DETAILED DESCRIPTION OF THE PREFERRED EMBODIMENTS

Below are details of a whisker-grown body, an electrochemical capacitor, and manufacturing methods of the same according to the present invention.

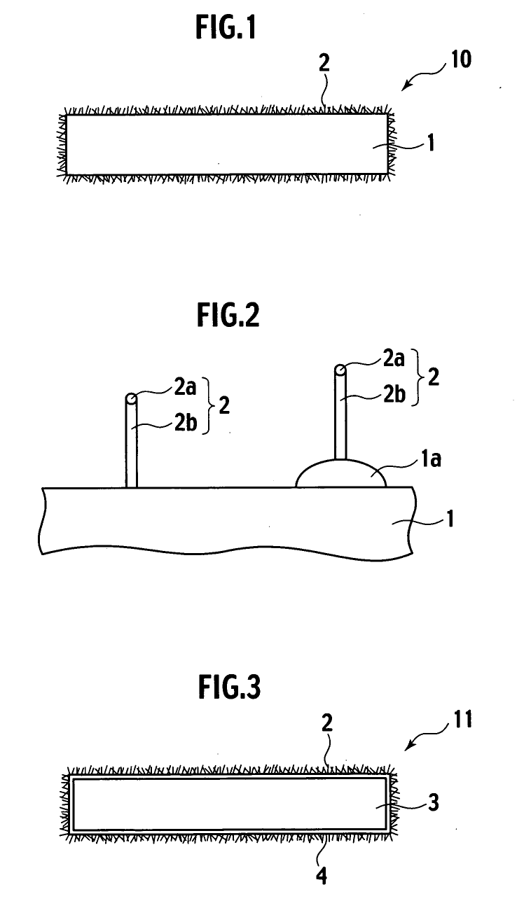

As shown in FIG. 1, a whisker-grown body 10 of the present invention has a raw material substrate 1 made of manganese-containing metal and/or ceramics. On the surface of the substrate 1, manganese dioxide-based whiskers 2 are grown.

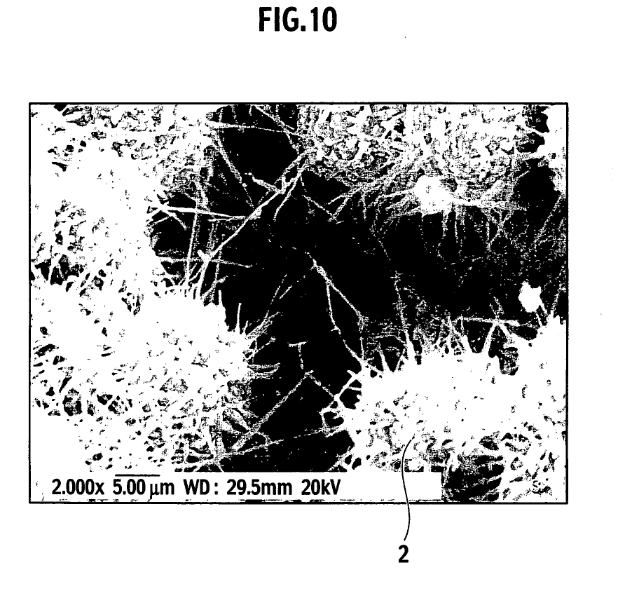

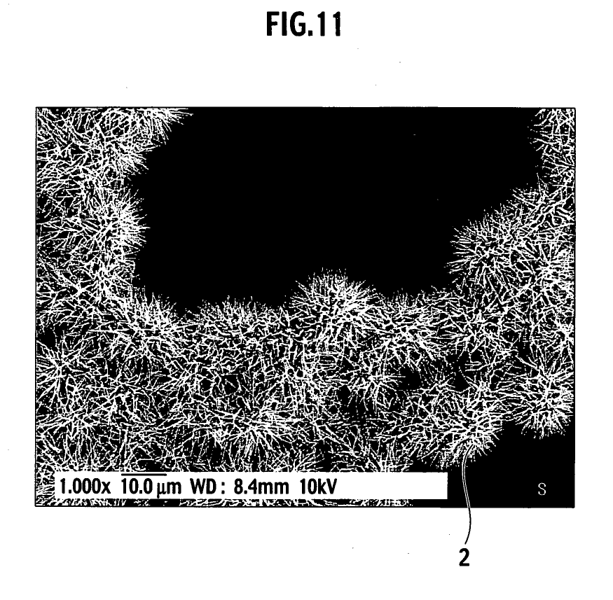

As shown in FIG. 2, each whisker 2 of the whisker-grown body 10 includes a ball-like head 2 based on metal, and a columnar shaft 2b based on an oxide. These whiskers 2 are grown not only on the surface of the substrate 1, but on bumps 1a on the surface as illustrated in FIG. 2. Because the whiskers 2 are formed on the bumps 1a of the substrate 1, the aggregations of the whiskers 2 have a sub-orbicular shape as seen in FIGS. 10 and 11.

Practically, an oxide constructing the shafts 2b of the whiskers 2 is a manganese dioxide. However, some impurities based on non-manganese components contained in the raw material substrate 1 are mixed into manganese dioxide, which is not avoidable. Therefore, in this invention, “manganese dioxide-based” means that the mass ratio of the manganese dioxide content in each whisker is 50% or higher to other component, as it has been proved separately that as long as a mass of manganese dioxide contained in a whisker is 50% or over, the whiskers do not fail to provide desired performance. Moreover, “metal and/or ceramics” stated earlier means only a metal or ceramics, or cermet, which is a combination of a metal and ceramics. Specifically, “metal and/or ceramics” includes a manganese-containing alloy, ceramics which contains oxide, carbide, nitride or boride of manganese, and cermet made of a metal and ceramics, at least one of which contains manganese.

Although such metal and/or ceramics containing manganese may be used as the raw material substrate 1, since manganese is susceptible to oxidation, an excessive manganese content contributes to oxidation of the surface and inside of the substrate 1. As a result, an electrical resistance value of the substrate 1 may become higher than that of a metal substrate. To avoid this problem, as shown in FIG. 3, a raw material substrate 3 which contains no manganese is used and a thin manganese-containing layer 4 is provided on the surface of the substrate 3. By using this, a whisker-grown body 11 with improved collection effectiveness is realized by avoiding reduction in electrode conductivity caused by oxidation of manganese that was not consumed by whiskers and left in an electrode. As for the manganese-containing layer 4, just like the foregoing raw material substrate 1, the manganese-containing metal and/or ceramics can be used. Any kind of metal can be used as a material of the raw material substrate 3 having the manganese-containing layer 4, as long as the substrate can maintain its shape after heat treatment performed for allowing whiskers to glow. Specific examples for such metal are iron, nickel, and an alloy thereof. Also, refractory metals such as tungsten and molybdenum, or noble metals such as platinum can be used for the substrate as well. As for the substrate having the manganese-containing layer 4, insulating materials such as ceramics may be used.

An manganese-containing alloy may be an ingot or a sintered alloy. As to the raw material substrate 1 or 3, a mesh or porous material may be used. Moreover, the raw material substrate 1 or 3 may be a mesh-like substrate or a porous substrate coated with metallic manganese powder, ferromanganese powder, or manganese-containing alloy powder, ceramic powder made of oxide, carbide, nitride, or boride containing manganese.

Each whisker 2 has preferably a thickness of 1 nm to 5 μm and a length of 10 nm to 50 μm. It is further preferred that manganese dioxide whiskers of this size are densely grown in every orientation on the surface of the substrate 1 or 3. Accordingly, the surface area of the substrate per unit volume or weight is increased, and, as a result, an effective area is increased and electrode efficiency is improved, which is advantageous in terms of using such a substrate as an electrode material.

Note that thickness and length of a whisker can be controlled by adjusting a content ratio of oxide-constituting elements in the raw material substrate 1 and manganese-containing layer 4. For example, by adjusting a content ratio of oxide-constituting elements in the raw material substrate 1 between 1 and 100% by mass, one can obtain whiskers each having a thickness of 2 nm to 100 μm and a length of 20 nm to 1000 μm. Meanwhile, by adjusting a content ratio of oxide-constituting elements in the substrate 1 between 3 and 50% by mass, one can get whiskers each having a thickness of 5 nm to 1 μm, and the length of 50 nm to 50 μm.

To be more specific, it has been confirmed that when a content of manganese (Mn) is changed between 10 and 80% by mass under the same heat treatment conditions, one can design whiskers, selecting specific size from the ranges of 10 nm and 5 μm for average thickness and 2 to 50 μm for average length. It has also been proved that, by increasing heat treatment temperature and reducing an inert gas flow rate, whiskers tend to be thicker.

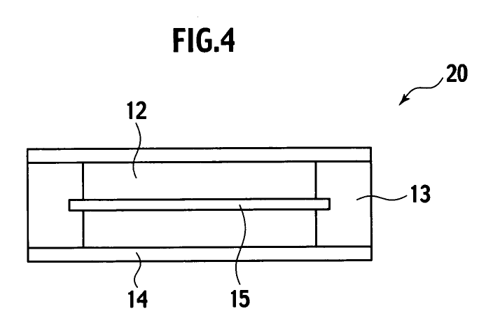

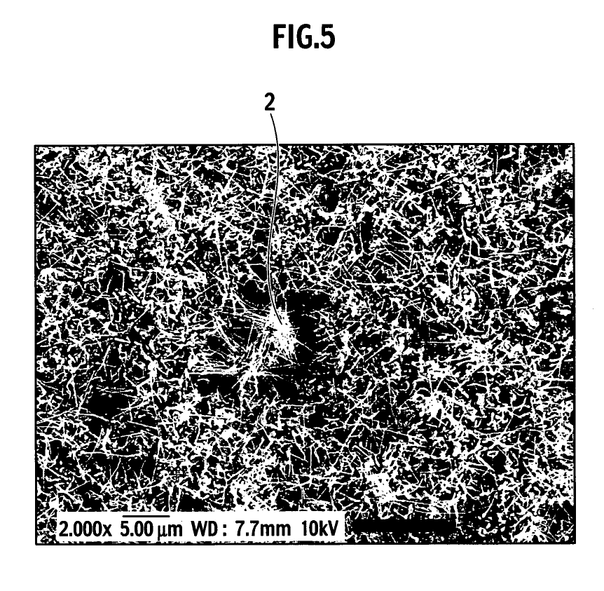

The whisker-grown body according to the present invention has manganese dioxide-based conductive whiskers and is preferably used as an electrode 12 of an electrochemical capacitor 20 as shown in FIG. 4. In such a case, it is preferred that the raw material substrate 1 or 3 be also conductive, and, more preferably, the conductivity of the raw material substrate is higher than that of the manganese dioxide whiskers. Accordingly, the raw material substrate 1 or 3 can also function as a collector, and, unlike a conventional technique for mixing collectors such as carbon powder, the entire surface of the whisker-grown body contributes to an electrochemical reaction. Thus, electrode efficiency of a cell is largely improved. Note that, in FIG. 4, Reference numerals 13, 14 and 15 represent a gasket, a collector, and a separator, respectively, and electrolysis solution is contained in the electrode 12. Further, in the electrochemical capacitor 20 in FIG. 4, the collector 14 is optional: since the whisker-grown body of the present invention has high conductivity and thus effective conduction of positive hole and electron is obtained, an electrochemical capacitor can function without a collector.

When the whisker-grown body of the present invention is used as an electrode of an electrochemical capacitor, it is particularly preferred that each manganese-dioxide whisker have a thickness ranging from 1 nm to 100 nm and a length ranging from 10 nm to 20 μm in order for the whisker-grown body to have an appropriate size of its uneven surface to fit the electrochemical capacitor. Activated carbon or the like used for an electric double layer capacitor has a large surface area but its ratio of mesopores that can be used as an electrode is relatively small. Therefore, if compared to activated carbon, by efficiently adjusting the uneven surface of the whisker-grown body to best fit the electrochemical capacitor, one can make the best use of its surface to work as an electrode.

It is also preferred that a whisker-grown body used for an electrochemical capacitor have a porous raw material substrate and that the average length of the manganese-dioxide whiskers be smaller than the average hole diameter of the porous raw material substrate. Therefore, the whiskers are grown within the small pores of the raw material substrate, resulting in an increase in surface area per unit volume of the electrode, and thus output power is further increased. Note that thickness and length of each whisker can be controlled by selecting appropriate ingredients for the raw material substrate or making adjustments of heat treatment temperature, inert gas flow rate, and the like.

Next, a manufacturing method of the whisker-grown body of the present invention is described. For fabricating the whisker-grown body of the present invention, what should be prepared first is, as stated earlier, a raw material substrate made of an alloy, ceramics, or cermet which contains manganese in various ways, a raw material substrate coated with metal or ceramics powder which contains manganese, or a raw material substrate having a manganese-containing layer on its surface.

The raw material substrate is then put in an atmosphere-adjustable reactor and heated in an inert gas atmosphere with a little amount of oxygen (first step). After this step, whiskers containing a low-oxidized manganese oxide such as manganese monoxide (MnO) are grown.

Inert gas used in the first step may be argon, nitrogen, helium, neon, krypton, xenon, radon, or an arbitrary mixture of them. However, typically, argon is used.

Moreover, in order to grow the oxidized whiskers, it is necessary to mix a very little amount of oxygen in the atmosphere. The preferred concentration of oxygen in the atmosphere is within a range from 1 to 1000 ppm, and an oxygen concentration ranging from 1 to 100 ppm is more preferred. This is because, after the inert gas is send into the reactor for the change of the inside atmosphere, the above amount of oxygen is usually left in a reactor.

Conditions of the heating treatment for the first step are determined in accordance with the size or shape of the reactor and the raw material substrate. For example, if the reactor capacity is 3 liters, the heating temperature between 700 and 1100 degrees centigrade is preferred. When performing heating treatment, if a reactor has the above-described capacity, it is preferred that the raw material substrate be treated for about 30 to 1000 minutes while supplying 0.1 to 5 liters of inert gas into the reactor per minute.

Next, the whiskers grown after the first step are heated again in an oxidized atmosphere (Second step). The whiskers are treated with heat for at least 1 hour in air, oxygen or ozone atmosphere at temperature of 200 to 400 degrees centigrade. Thus, manganese oxide (MnO or the like) with a small amount of bonded oxygen obtained in the first step is further oxidized and becomes manganese dioxide (MnO₂). As a result, the whisker-grown body of the present invention with manganese-dioxide whiskers grown on the raw material substrate is formed.

If heating temperature is lower than 200 degrees centigrade in the second step, the whiskers grown in the first step are scarcely oxidized. On the other hand, if heating temperature is above 400 degrees centigrade, the whiskers are stabilized with a low valence oxide such as Mn₂O₃ and Mn₃O₄ and no longer oxidized, while the raw material substrate is oxidized and may become fragile.

Below are descriptions of specific Examples of the present invention. However, note that the present invention is not limited to the Examples.

### EXAMPLE 1

A porous material made of Ni—Mn alloy powder (containing 50% by mass of Mn) with the average particle size of 5 μm was shaped into a raw material substrate having an average pore size of 20 μm, the voidage of 30%, a diameter of 10 mm and thickness of 1 mm.

The raw material substrate was put into an air-filled furnace. First, the atmosphere within the furnace was air, but in the first step, Ar gas was gradually introduced into the furnace at the rate of 1 L/min to fill the furnace with the inert gas while increasing temperature to 1000 degrees centigrade at the rate of 1000° C./hour. Thereafter, the temperature was held at 1000 degrees centigrade for two hours, and cooled down until the furnace temperature dropped down to the room temperature. Thus, whiskers were grown on the surface of the raw material substrate.

Next, in the second step, after air was introduced into the furnace, the substrate was treated with heat for 10 hours at 300 degrees centigrade, so that the whiskers obtained in the first step were oxidized. After the oxidation, the average diameter and length of the whiskers were 200 nm and 2 μm, respectively. FIG. 5 shows an electron microscope photograph of the whiskers obtained in Example 1.

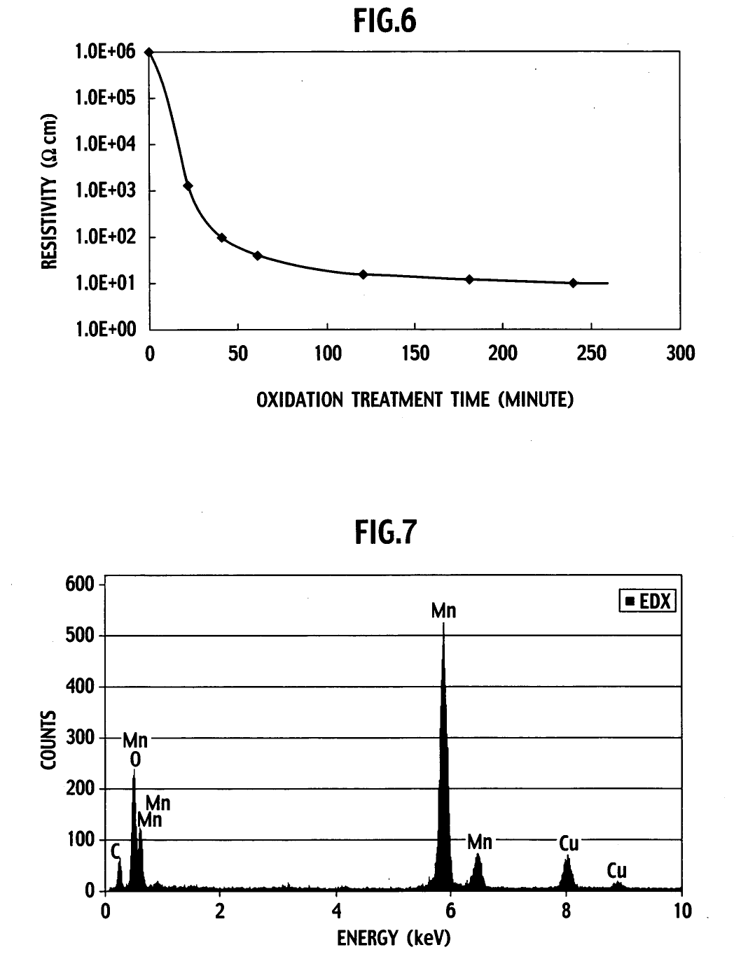

FIG. 6 is a graph showing the change in the whiskers' conductivity relative to oxidation time in the second step. The graph indicates that, as the heat treatment is performed longer, the resistivity becomes lower, and thus the conductivity becomes higher.

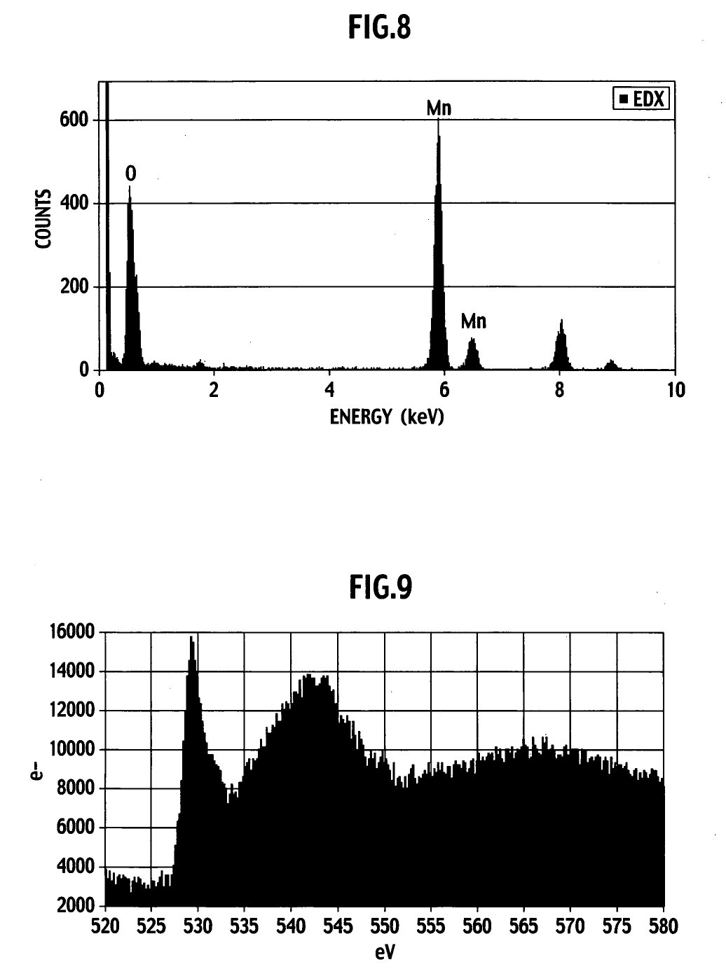

FIGS. 7 and 8 show the results of component analysis using EDX for the whiskers before and after the oxidation treatment in the second step. From FIGS. 7 and 8, it was confirmed that the ratio of Mn to O in the whiskers was 5 to 55 before the oxidation, but changed to 31 to 69 after the treatment.

Further, FIG. 9 shows O—K Edge ELNES of the whiskers after the oxidation treatment in the second step. The graph describes the bonding state between oxygen atoms and manganese atoms within the whiskers and, from the fact that the result is almost identical to the MnO₂ spectrum shown in Hiroki Kurata and Christian Colliex, Phys. REV. B48, 2102-2108 (1993), it was proved that the main ingredient of the whiskers was MnO₂. The results shown in FIGS. 7 to 9 made clear that the heating treatment in the oxidizing atmosphere in the second step changed the main ingredient of the whiskers from MnO to MnO₂.

### EXAMPLE 2

First of all, a porous material made of Ni—Mn alloy powder (containing 50% by mass of Mn) with the average particle size of 20 μm was shaped into a raw material substrate having diameter of 10 mm and thickness of 1 mm, with the voidage of 50%. The substrate was put in a furnace, and the temperature was increased up to 900 degrees centigrade in 1.5 hours in the atmosphere containing 20 ppm oxygen while Ar gas was introduced at the rate of 1 L/min. The temperature was held at 900 degrees centigrade for two hours and cooled until the furnace temperature is down to the room temperature, and whiskers were grown (First step). The substrate was further annealed for 60 hours in an atmosphere at 300 degrees centigrade to oxidize the whiskers (Second step). As a result, whiskers having the average diameter of 200 nm and the average length of 10 μm were densely grown over the surface of the substrate. FIG. 10 shows an electron microscope photograph of the whiskers obtained in Example 2.

### EXAMPLE 3

First of all, a form metal nickel substrate (manufactured by Mitsubishi Materials Corporation) with the average pore size of 50 μm was prepared, and a 5μm-thick manganese-containing layer made of Mi—Ni (containing 50% by mass of Mn) was formed on the surface of the substrate by a DC sputtering method, and thereby a raw material substrate was prepared.

The substrate was put in a furnace, and the temperature was increased up to 900 degrees centigrade in 1.5 hours in the atmosphere containing 50 ppm oxygen while Ar gas was being introduced into the furnace at the rate of 1 L/min. The temperature was held at 900 degrees centigrade for two hours and cooled until the furnace temperature is down to the room temperature, and whiskers were grown (First step). The substrate was further annealed for 60 hours in atmosphere at 300 degrees centigrade to oxidize the whiskers (Second step). As a result, whiskers having the average diameter of 100 nm and the average length of 10 μm were densely grown over the surface of the substrate. FIG. 11 shows an electron microscope photograph of the whiskers obtained in Example 3.

### COMPARATIVE EXAMPLE

80% by mass of activated carbon and 10% by mass of acetylene black powder, both having the average particle size of 5 μm, were mixed together, and the surface of each particles of this carbonaceous powder was supported by 10% by mass of manganese oxide by a sol-gel process. The manganese oxide-supported carbonaceous material thus obtained was dried and then mixed into 10% by mass of a polymer binder. The resultant material was rolled onto nickel mesh and then punched out to obtain a circular sheet with diameter of 10 mm and thickness of 1 mm. The sheet was then dried at 250 degrees centigrade.

Electrode Evaluation

The whisker-grown bodies in Examples 1 and 2 and the MnO₂-supported nickel mesh material obtained by the sol-gel process in Comparative Example were used as electrodes of electrochemical capacitors. Capacitances and cycle characteristics of the capacitors were compared through measurements of cyclic voltammetry.

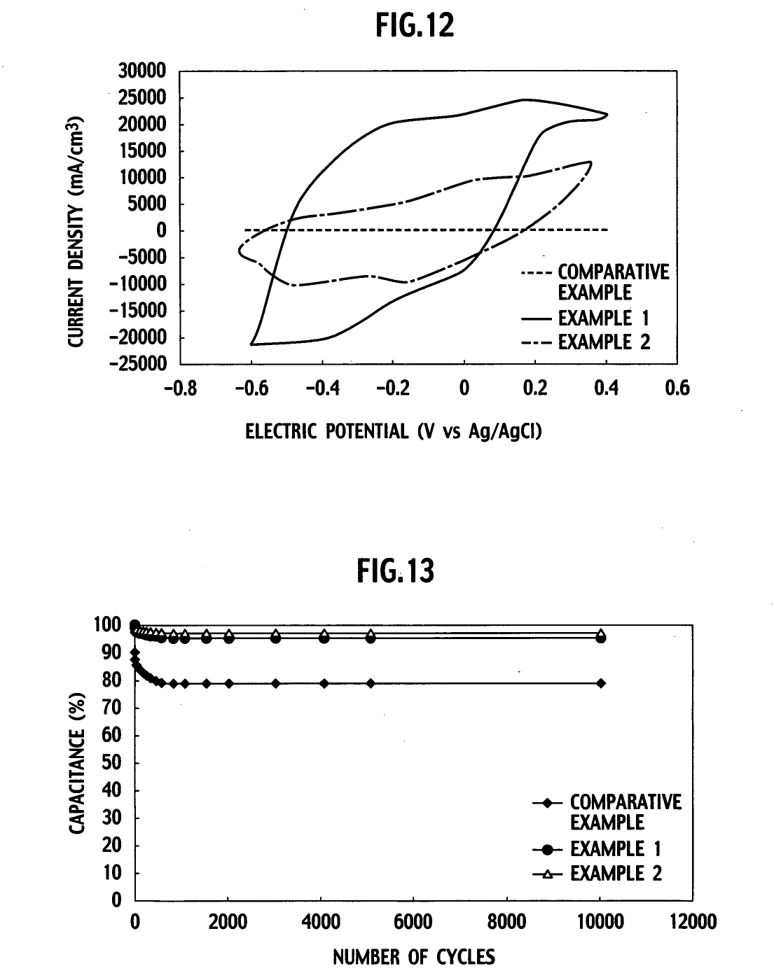

In other words, the whisker-grown bodies of Examples 1 and 2, and the electrode made of the nickel mesh material obtained in Comparative Example were used as working electrodes, and platinum plates and silver-silver chloride electrodes were used as the counter electrodes and reference electrodes, respectively. Also, 1M potassium sulfate (K₂SO₄) solution was used as electrolyte and the rate of scan of potential was set at 50 mV/s. Then, measurements of cyclic voltammetry were carried out. The results of the measurements are shown in FIG. 12.

From the graph shown in FIG. 12, as for Examples 1 and 2, the capacitances per unit volume at the second cycle of the cyclic voltammetry measurement were 330 F/cm³ and 120 F/cm³, respectively. On the contrary, for Comparative Example, the capacitance was only 4 F/cm³.

The cyclic voltammetry was measured repeatedly and charging capacitance and discharging capacitance were calculated respectively. From the calculation, changes in capacitance in each cycle are compared, and results of the comparison are shown in FIG. 13. In FIG. 13, the capacitance change for each cycle is expressed in percentage when the capacitance shown in FIG. 12 is deemed to 100%. For Comparative Example using the MnO₂-supported electrode made of the sol-gel process, the capacitance is reduced to 80% at about 400 cycles, whereas Examples 1 and 2 using the electrodes made of the whisker-grown bodies of the present invention maintained their capacitances at 95% or higher even after 10,000 cycles. The same capacitance evaluations were carried out for Example 3 by cyclic voltammetry measurements, and the result was 31 F/cm³, and maintained 95% or more of the capacitance after 10,000 cycles similarly to Examples 1 and 2.

Below is a table 1 showing the results of the measurements described above.

TABLE 1

| | Capacitance at | Capacitance |
|---|---|---|
| | 2nd Cycle | after 10,000 Cycles |
| Example 1 | 330 F/cm³ | 95.3% |
| Example 2 | 120 F/cm³ | 96.5% |
| Example 3 | 31 F/cm³ | 95.7% |
| Comparative | 4 F/cm³ | 78.6% |
| Example | | |

According to the present invention, manganese dioxide-based whiskers are grown on a raw material substrate made of a manganese-containing metal and/or ceramics or on a raw material substrate having a manganese-containing layer on its surface. Thus, the whisker-grown body is made. Therefore, the surface area per unit volume becomes larger (several tens to hundreds times) than a flat plate. Further, since the whiskers are actually made of manganese dioxide, the whisker-grown body is conductive. Therefore, the whisker-grown body can be used for various purposes, for example as various kinds of electrodes, filters, reforming catalysts, or catalyst-support bodies.

When such whisker-grown body is used as an electrode for an electrochemical capacitor, because of the fact that the surface area thereof is large and that whisker's diameter and length can be optimized, electrode effectiveness of a cell is greatly improved, and power output is increased. In particular, by using a highly conductive material such as metal for the raw material substrate, a collector will no longer necessary, and, in addition, internal resistivity decreases and responsiveness of an electrode is enhanced.

Furthermore, according to the manufacturing method of the present invention, a raw material substrate made of a manganese-containing metal and/or ceramics or a raw material substrate having a manganese-containing layer on its surface is put under heat treatment (First step) in an inert gas atmosphere containing a small amount of oxygen. As a result, whiskers made of a manganese-containing oxide are grown on the surface of the raw material substrate. Thereafter, the substrate is heated further in an oxidizing atmosphere, for example, for 1 hour or longer in an atmosphere at 200 to 400 degrees centigrade (Second step). Accordingly, manganese oxide such as manganese monoxide (MnO) contained in the whiskers made after the first step are further oxidized in the second step and become manganese dioxide (MnO₂). In the above manner, a whisker-grown body on which manganese dioxide-based whiskers are grown on the surface of a raw material substrate is manufactured easily and inexpensively.

The entire contents of Japanese Patent Applications No. P2005-38994 with a filing date of Feb. 16, 2005 and No. P2005-354446 with a filing date of Dec. 8, 2005 are herein incorporated by reference.

Although the invention has been described above by reference to certain embodiments of the invention, the invention is not limited to the embodiments described above will occur to these skilled in the art, in light of the teachings. The scope of the invention is defined with reference to the following claims.

What is claimed is:

1. A whisker-grown body, comprising:
a raw material substrate made of manganese-containing metal and/or ceramics; and
a whisker containing 50% by mass or more of manganese dioxide and formed on a surface of the raw material substrate.

2. The whisker-grown body of claim 1,
wherein the whisker has a thickness ranging from 1 nm to 5 μm and a length ranging from 10 nm to 50 μm.

3. The whisker-grown body of claim 1,
wherein conductivity of the raw material substrate is higher than that of the whisker.

4. The whisker-grown body of claim 1,
wherein the whisker includes a boll-like metal head and columnar shaft made of an oxide.

5. A whisker-grown body, comprising:
a raw material substrate having a manganese-containing layer which is made of a manganese-containing metal and/or ceramics and is formed on a surface thereof; and
a whisker containing 50% by mass or more of manganese dioxide and formed on a surface of the manganese-containing layer.

6. The whisker-grown body of claim 5,
wherein the whisker has a thickness ranging from 1 nm to 5 μm and a length ranging from 10 nm to 50 μm.

7. The whisker-grown body of claim 5,
wherein conductivity of the raw material substrate is higher than that of the whisker.

8. The whisker-grown body of claim 5,
wherein the whisker includes a boll-like metal head and columnar shaft made of an oxide.

9. An electrochemical capacitor, comprising:
an electrode comprising:
a raw material substrate made of manganese-containing metal and/or ceramics; and
a whisker containing 50% by mass or more of manganese dioxide and formed on a surface of the raw material substrate.

10. The electrochemical capacitor of claim 9,
wherein the whisker has a thickness ranging from 1 nm to 100 nm and a length ranging from 10 nm to 20 μm.

11. An electrochemical capacitor, comprising:
an electrode comprising:
a raw material substrate having a manganese-containing layer which is made of a manganese-containing metal and/or ceramics and is formed on a surface thereof; and
a whisker containing 50% by mass or more of manganese dioxide and formed on a surface of the manganese-containing layer.

12. The electrochemical capacitor of claim 11,
wherein the whisker has a thickness ranging from 1 nm to 100 nm and a length ranging from 10 nm to 20 μm.

13. A manufacturing method of a whisker-grown body, comprising:
providing a raw material substrate made of manganese-containing metal or/and ceramics or a raw material substrate having a manganese-containing layer made of manganese-containing metal or/and ceramics;
forming a whisker on a surface of the raw material substrate by a first heating treatment in an inert gas atmosphere containing oxygen, the whisker being made of a manganese-containing oxide; and
performing a second heating treatment on the whisker in an oxidizing atmosphere.

14. The manufacturing method of a whisker-grown body of claim 13,
wherein the second heating treatment is performed for one hour or longer in an atmosphere at 200 to 400 degrees centigrade.

15. The manufacturing method of a whisker-grown body of claim 13,
wherein oxygen concentration for the first heat treatment is within a range from 1 to 1000 ppm.
